(19) United States
(12) Patent Application Publication
(10) Pub. No.: US 2007/0257322 A1
(43) Pub. Date: Nov. 8, 2007

(54) Hybrid Transistor Structure and a Method for Making the Same

(75) Inventors: Zhonghai Shi, Austin, TX (US); Voon-Yew Thean, Austin, TX (US); Ted R. White, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/382,149

(22) Filed: May 8, 2006

(51) Int. Cl. H01L 29/76; H01L 29/94; H01L 31/00; H01L 21/8238

(52) U.S. Cl. 257/371; 438/199

(57) ABSTRACT

A topography (40) is provided which includes a device having a transistor formed from a stack of semiconductor layers (42/46). The different semiconductor layers are spaced apart by a gate (60) and by support structures (48) comprising a material having different etch characteristics than the materials of the spaced apart semiconductor layers. The device includes a first transistor channel (76) within the upper semiconductor layer and, in some cases, further includes a second transistor channel within the lower semiconductor layer. The resulting hybrid transistor structure may be fabricated as one of a pair of CMOS transistors, the other of which may include the same configuration or a different configuration. A method for fabricating the hybrid transistor structure includes forming a gate structure surrounding a suspended portion (52) of an upper patterned semiconductor layer (53) and extending down to a surface of a lower semiconductor layer (42).

### BACKGROUND OF THE INVENTION

1. Field of the Invention

This invention generally relates to semiconductor processing and, more specifically, to a method for fabricating a hybrid transistor device.

2. Description of the Related Art

The following descriptions and examples are not admitted to be prior art by virtue of their inclusion within this section.

A conventional metal-oxide-semiconductor-field-effect-transistor (MOSFET) has a configuration in which a gate comprising stacked layers of an electrode and a dielectric film are arranged above a channel region of a semiconductor substrate. Such a conventional design may be described as a single-gate-sided channel transistor since the gate is arranged on only one side of (i.e., above) the channel. It is generally recognized that single-gate-sided channel transistors exhibit operational characteristics, including leakage current, drive current, and sub-threshold slope, that are less than ideal. In addition, it is appreciated that transistor performance degradation due to such non-superlative characteristics becomes more prevalent as transistor dimensions decrease. In an attempt to address such problems, multiple-gate-sided channel transistor structures have been proposed.

In general, multiple-gate-sided channel transistors refer to transistors having gates formed on two or more sides of a transistor channel. An example of a multiple-gate-sided channel transistor is a “Fin FET,” so named because the transistor channel is a fin or wall of silicon positioned above an underlying substrate and between two opposing gates. The opposing gates offer better control of the channel field within the fin as compared to conventional single-gate-sided channel transistors. As a result, increased drive currents are realized and short-channel effects are lessened. In some cases, a plurality of fins (i.e., channels) extending to common source and drain regions may be provided upon a substrate to increase current capacity within a transistor. Such a configuration, however, may undesirably occupy valuable die space. Multiple-gate-sided transistors having a stacked configuration of channels have been proposed, but such structures generally require a complex sequence of processing steps, undesirably increasing the process time and costs of fabricating a device.

### BRIEF DESCRIPTION OF THE DRAWINGS

Other objects and advantages of the invention will become apparent upon reading the following detailed description and upon reference to the accompanying drawings in which:

FIG. 1 depicts a partial perspective view of a semiconductor topography with a multiple-gate-sided transistor structure having a gate arranged about an upper semiconductor layer and extending down to a lower semiconductor layer;

FIG. 2 depicts a partial perspective view of a semiconductor topography with a multiple-gate-sided transistor structure having a gate arranged about three different segments of an upper semiconductor layer and extending down to a lower semiconductor layer;

FIG. 3 depicts a partial cross-sectional view of a semiconductor topography having an intermediate layer formed between an upper semiconductor layer and a lower semiconductor layer;

FIG. 4 depicts a partial plan view of the semiconductor topography depicted in FIG. 3 subsequent to patterning the upper semiconductor layer;

FIG. 5 depicts a partial cross-sectional view of the semiconductor topography depicted in FIG. 4 taken along line 56;

FIG. 6 depicts a partial plan view of the semiconductor topography depicted in FIG. 3 subsequent to patterning the upper semiconductor layer in an alternative manner;

FIG. 7 depicts a partial cross-sectional view of the semiconductor topography depicted in FIG. 6 taken along line 56;

FIG. 8 depicts a partial cross-sectional view of the semiconductor topography depicted in FIG. 6 subsequent to patterning the upper semiconductor layer;

FIG. 9 depicts a partial cross-sectional view of the semiconductor topography depicted in FIG. 8 taken along line 56;

FIG. 10 depicts a partial plan view of the semiconductor topography depicted in FIG. 8 subsequent to etching the intermediate layer to suspend a portion of the upper semiconductor layer above the lower semiconductor layer;

FIG. 11 depicts a partial cross-sectional view of the semiconductor topography depicted in FIG. 10 taken along line 56;

FIG. 12 depicts a partial cross-sectional view of the semiconductor topography depicted in FIG. 11 taken along line 58;

FIG. 13 depicts a partial plan view of the semiconductor topography depicted in FIG. 12 subsequent to the formation of a transitional gate structure in a region comprising a suspended portion of the upper semiconductor layer;

FIG. 14 depicts a partial cross-sectional view of the semiconductor topography depicted in FIG. 13 taken along line 56;

FIG. 15 depicts a partial cross-sectional view of the semiconductor topography depicted in FIG. 13 taken along line 58;

FIG. 16 depicts a partial plan view of the semiconductor topography depicted in FIG. 13 subsequent to further etching the transitional gate structure to form a multiple-sided gate structure;

FIG. 17 depicts a partial cross-sectional view of the semiconductor topography depicted in FIG. 16 taken along line 56;

FIG. 18 depicts a partial cross-sectional view of the semiconductor topography depicted in FIG. 16 taken along line 58;

FIG. 19 depicts a partial cross-sectional view of the semiconductor topography depicted in FIG. 13 in an alternative embodiment and subsequent to the formation of a gate which exposes upper surfaces of the upper semiconductor layer;

FIG. 20 depicts a partial cross-sectional view of the semiconductor topography depicted in FIG. 18 subsequent to the formation of lightly doped regions within exposed portions of the lower and upper semiconductor layers;

FIG. 21 depicts a partial cross-sectional view of the semiconductor topography depicted in FIG. 20 subsequent to the formation of spacers along the gate and the formation of source and drain regions within exposed portions of the lower and upper semiconductor layers in alignment with the spacers; and

FIG. 22 depicts a partial cross-sectional view of a semiconductor topography in which a single-gate-sided transistor is formed adjacent to a multiple-gate-sided transistor structure.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

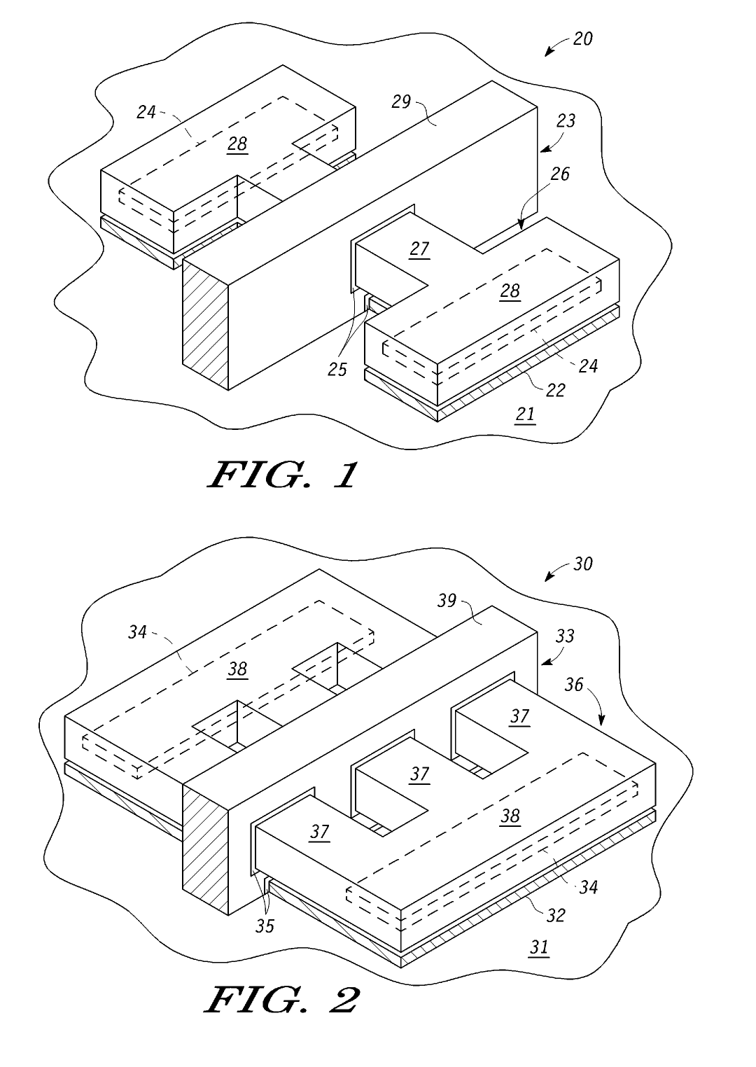

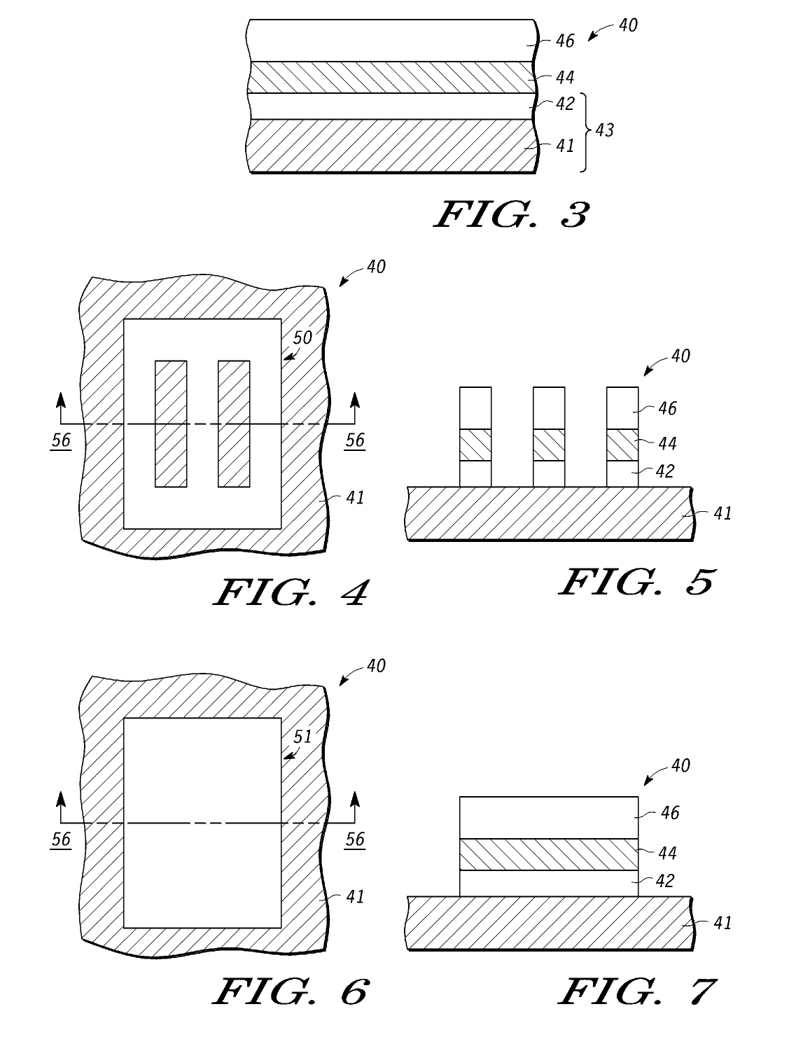

With regard to the drawings, exemplary configurations of devices including transistors formed from a stacked configuration of spaced apart semiconductor layers are shown in FIGS. 1 and 2. In addition, FIGS. 3-22 illustrate exemplary methods for fabricating such devices. As shown in FIG. 1, semiconductor topography 20 includes multiple-sided gate structure 23 surrounding a portion of upper semiconductor layer 26 and extending down to an upper surface of lower semiconductor layer 22, all of which are formed above lower substrate portion 21. In general, the term “multiple-sided gate structure” may refer to a gate structure having a plurality of surfaces arranged directly adjacent to surfaces of one or more semiconductor layers included within or used for the fabrication of one or more transistors. As shown in FIG. 1, multiple-sided gate structure 23 includes gate dielectrics 25 disposed upon surfaces of semiconductor layers 22 and 26 and further includes gate electrode 29 arranged thereon. As will be described in more detail below, multiple-sided-gate structure 23 is included within a transistor having a multiple-gate-sided transistor channel formed within semiconductor layer 26. In particular, the portion of upper semiconductor layer 26 surrounded by multiple-sided gate structure 23 serves as a multiple-gate-sided transistor channel and adjacent portions of upper semiconductor layer 26 along narrow portion 27 and broader portions 28 serve as source and drain regions extending from the multiple-gate-sided transistor channel.

As further described below, multiple-sided gate structure 23 may, in some cases, be further common to a transistor channel within a portion of lower semiconductor layer 22. In particular, lower semiconductor layer 22 may include a transistor channel below the portion of multiple-sided gate structure 23 arranged upon semiconductor layer 22. In addition, semiconductor layer 22 may include source and drain regions extending from the transistor channel along the same respective directions as the source and drain regions within upper semiconductor layer 26. In such cases, the transistor channel within semiconductor layer 22 and the source and drain regions extending therefrom may be part of the transistor comprising the multiple-gate-sided transistor channel within upper semiconductor layer 26 or may be part of a different transistor. In yet other cases, lower semiconductor layer 22 may alternatively be void of a channel region and source and drain regions. In particular, the formation of a transistor may be restricted, in some cases, to upper semiconductor layer 26. In any case, it is noted that source and drain regions are not specifically depicted within semiconductor layers 22 and 26 in FIG. 1 to simplify the drawing and to allow the figures to generally represent the different embodiments of whether a transistor is formed within lower semiconductor layer 22 as described above.

In addition to being spaced apart from semiconductor layer 22 by multiple-sided gate structure 23, semiconductor layer 26 is spaced above semiconductor layer 22 by support structures 24 as shown in FIG. 1. Support structures 24 are outlined by dotted lines in FIG. 1 denoting their positions coupled to and interposed between portions 28 of semiconductor layer 26 and underlying portions of semiconductor layer 22. As explained below with regard to the method for fabricating the devices described herein, support structures 24 include a material having different etch characteristics than semiconductor layers 22 and 26, specific examples of which are described below in reference to FIG. 3. In some embodiments, support structures 24 may include a dielectric material and, therefore, may electrically isolate respective source and drain regions within semiconductor layers 22 and 26. In such cases, the device structure comprising semiconductor topography 20 may include two transistors which share a multiple-sided gate structure. In other embodiments, support structures 24 may include a semiconductor or a conductive material and, therefore, may electrically connect respective source and drain regions within semiconductor layers 22 and 26. In such cases, the device comprising semiconductor topography 20 may be a single transistor having multiple channels which share a multiple-sided gate structure. In alternative cases, as noted above, source and drain regions and channel regions may not be formed within semiconductor layer 22 and, consequently, support structures 24 may not electrically isolate or connect source and drain regions.

In any configuration, the device structure comprising semiconductor topography 20 may be referred to herein as a hybrid transistor structure since the structure may be used to fabricate a device utilizing a multiple-gate-sided transistor channel formed within an upper semiconductor layer and, in some embodiments, further include a transistor channel formed within a lower semiconductor layer. It is noted that the hybrid transistor structures described herein are not restricted to having one multiple-gate-sided transistor channel as described for the device illustrated in FIG. 1. In particular, the patterned upper semiconductor layer of a hybrid transistor structure is not limited to having a single segment about which a multiple-sided gate structure may be formed. An exemplary configuration of a hybrid transistor structure having a plurality of multiple-gate-sided transistor channels is shown in FIG. 2. In particular, FIG. 2 illustrates semiconductor topography 30 including multiple-sided gate structure 33 surrounding multiple portions of patterned semiconductor layer 36 and extending down to the upper surface of semiconductor layer 32, all of which is formed above lower substrate portion 31. Although semiconductor layer 36 is shown having three segments 37 around which multiple-sided gate structure 33 is formed, semiconductor layer 36 may include any number of segments extending between joining portions 38.

Similar to the configuration of the hybrid transistor structure described in reference to FIG. 1, semiconductor topography 30 includes support structures 38 interposed between semiconductor layers 32 and 36. In addition, multiple-sided gate structure 33 includes gate dielectrics 35 disposed upon the surfaces of semiconductor layers 32 and 36 and further includes gate electrode 39 arranged thereon. The portions of semiconductor layer 36 surrounded by multiple-sided gate structure 33 serve as a plurality of multiple-gate-sided transistor channels and adjacent portions of semiconductor layer 36 serve as source and drain regions extending from the multiple-gate-sided transistor channels. In some embodiments, semiconductor layer 32 may include a transistor channel below the portion of multiple sided gate structure 33 arranged upon semiconductor layer 32. In such cases, semiconductor layer 32 may further include source and drain regions extending from the transistor channel along the same respective directions as the source and drain regions within semiconductor layer 36. As explained below with regard to the method for fabricating the devices described herein, however, lower semiconductor layer 32 may alternatively be void of a channel region and source and drain regions. In particular, the formation of a transistor may be restricted, in some cases, to patterned semiconductor layer 36.

Turning back to FIG. 1, lower semiconductor layer 22 is shown patterned in alignment with upper semiconductor layer 26. Alternatively stated, semiconductor layers 22 and 26 are shown to have substantially equivalent pattern layouts. In some cases, similar layout configurations may be advantageous for optimizing short channel characteristics of a transistor formed within lower semiconductor layer 22. In other embodiments, lower semiconductor layer 22 may have a different layout pattern than upper semiconductor layer 26, such as shown for lower semiconductor layer 32 in the device depicted in FIG. 2. In particular, semiconductor layer 32 in FIG. 2 is patterned as a contiguous block layer absent any openings coinciding with the openings of upper semiconductor layer 36 (i.e., between segments 37). Such a layout pattern relative to the pattern of upper semiconductor layer 36 may be desirable for easing quantization of electrical gate widths within a transistor formed from both semiconductor layers 32 and 36. It is noted that although FIG. 2 illustrates lower semiconductor layer 32 having outer peripheral edges in alignment with upper semiconductor layer 36, the pattern of lower semiconductor layer 32 is not necessarily so limited. In particular, the shape, size, and pattern of lower semiconductor layer 32 may vary widely depending on the design specifications of the ensuing device and, therefore, may differ from the layouts depicted in FIGS. 1 and 2.

It is noted that layers or structures other than those shown in FIGS. 1 and 2 may be formed among the hybrid transistor structures described in reference thereto. In particular, spacers may be formed along the sidewalls of the multiple sided gate structures and as well as silicides upon adjacent portions of the semiconductor layers. In addition, a dielectric layer may be formed over the hybrid transistor structures such that additional layers or structures, such as metallization lines, may be formed thereon. The dielectric layer may fill the regions underlying the patterned upper semiconductor layer and, consequently, such regions may not be suspended as illustrated in FIGS. 1 and 2. Such a dielectric layer as well as silicides and spacers are not shown in FIGS. 1 and 2 to simplify the drawings and emphasize the relative arrangement of components within the hybrid transistor structures described herein. It is further noted that the components depicted in FIGS. 1 and 2 are not necessarily drawn to scale. In particular, the dimensions of the components within the hybrid transistor structures described herein may vary widely and, consequently, should not be restricted to the depictions of the drawings.

An exemplary method for fabricating a hybrid transistor structure is outlined in FIGS. 3-22. Although the method is described specifically described in reference to forming the structure illustrated in FIG. 2, the method is not necessarily so limited. In particular, the method may be used to form any hybrid transistor structure having a multiple-gate-sided channel transistor formed from a stacked configuration of semiconductor layers as generally described in reference to FIGS. 1 and 2. As shown in FIG. 3, the method may include semiconductor topography 40 having a stack of layers, namely upper semiconductor layer 46 formed above intermediate layer 44, which in turn is formed above substrate 43 having lower semiconductor layer 42 formed above lower substrate portion 41. It is noted that additional layers may be arranged above or below any or all of lower substrate portion 41, lower semiconductor layer 42, intermediate layer 44, and upper semiconductor layer 46 and, consequently, the method is not necessarily restricted to the topography depicted in FIG. 3. In any case, lower semiconductor layer 42, intermediate layer 44, and upper semiconductor layer 46 may refer to the layers used to respectively fabricate semiconductor layers 22 and 32, support structures 24 and 34, and semiconductor layers 36 and 46 depicted in FIGS. 1 and 2. Consequently, the exemplary materials and thicknesses noted below for each layer may correlate to the corresponding components of the hybrid transistor structures depicted in FIGS. 1 and 2.

In some cases, substrate 43 may be a bulk wafer substrate, such as a monocrystalline silicon wafer or a silicon-germanium wafer, wherein semiconductor layer 42 represents an upper portion slated for the formation of a transistor and lower substrate portion 41 represents underlying regions of the wafer. In other embodiments, substrate 43 may be a semiconductor-on-insulator (SOI) substrate, having semiconductor layer 42 as a thin layer of a semiconductor material arranged upon an insulating material, such as silicon oxide, glass, or sapphire, which in turn is arranged upon a substrate. The insulating material and underlying substrate, in such cases, may make up lower substrate portion 41 depicted in FIG. 3. In general, the insulating layer may include a dielectric material, such as silicon dioxide, silicon nitride, silicon oxynitride, or any combination of such layers. In some cases, the underlying substrate may be a bulk substrate wafer of a semiconductor material. In other embodiments, the underlying substrate may include multiple layers, at least one of which includes a semiconductor material. Utilizing a substrate wafer having a semiconductor material has generally proven effective for the fabrication of integrated circuits in the semiconductor industry, but other substrate materials may be considered for semiconductor topography 40. For example, in some cases, the underlying substrate may include or may be entirely made of a conductive material.

In any case, an SOI substrate may be particularly advantageous for the formation of fully depleted transistor channels. In particular, semiconductor layer 42 may be configured to have a relatively shallow depth, such as but not limited to one-third or less than the length of a gate slated to be formed thereon, thereby facilitating a channel formed therein to be fully depleted. A further advantage of an SOI substrate is that field oxide isolation regions may be omitted from the topography in some embodiments. In particular, electrical isolation between regions of semiconductor topography 40 may be implemented by patterning lower semiconductor layer 42 to expose the insulating layer of lower substrate portion 41 as described in more detail in reference to FIGS. 4-7. Such a manner of implementing isolation among regions of semiconductor topography 40 may involve fewer steps than the formation of field oxide regions within a bulk wafer substrate, increasing processing time and reducing costs.

In general, lower semiconductor layer 42 and upper semiconductor layer 46 may include semiconductor materials. As used herein, a semiconductor material may generally refer to a material with electrical conductivity between that of a conductor and that of an insulator through which conduction takes place by way of holes and electrons. Although dopants may be used to vary the conductivity of a semiconductor material, such levels of conductivity are generally between those of a conductor and an insulator. In some embodiments, a semiconductor material may be described in reference to its non-dopant elements, independent of the type and concentration of dopants included therein, if any. More specifically, a semiconductor material may be described as a material in which its one or more non-dopant elements are selected essentially from Group IV of the periodic table or, alternatively, may refer to a material in which its plurality of synthesized non-dopant elements are selected from Groups II through VI of the periodic table.

Examples of Group IV semiconductor materials which may be suitable for semiconductor layers 42 and/or 46 include silicon, germanium, alloys of silicon and germanium (“silicon-germanium”), alloys of silicon and carbon (“silicon-carbon”), alloys of silicon, germanium and carbon (“silicon-germanium-carbon”), and the like. Examples of Group III-V materials suitable for semiconductor layers 42 and/or 46 include gallium arsenide, aluminum gallium arsenide, indium gallium arsenide, and the like. Other semiconductor materials are also possible for semiconductor layers 42 and 46. It is noted that the nomenclature of semiconductor materials may generally refer to the non-dopant compositions of the materials consisting essentially of the referenced elements, but the materials are not restrained from having non-dopant impurities and/or dopants therein. For example, silicon-germanium has a non-dopant composition consisting essentially of silicon and germanium, but is not restricted to having dopants and/or impurities of other elements selected from Groups II through VI of the periodic table.

In some embodiments, semiconductor layers 42 and 46 may include the same semiconductor materials (i.e., the same collection non-dopant elements, independent of the type and concentration of dopants included therein, if any). In other embodiments, semiconductor layers 42 and 46 may include different semiconductor materials. In any case, semiconductor layers 42 and/or 46 may be substantially undoped or may be doped either n-type or p-type. Furthermore, crystal orientations of semiconductor layers 42 and 46 may be the same or different, as described in more detail below with regard to the formation of semiconductor layer 46 upon intermediate layer 44.

In general, intermediate layer 44 may include a material having different etch characteristics than semiconductor layers 42 and 46 such that a patterned portion of upper semiconductor layer 46 may be subsequently suspended above lower semiconductor layer 42 as described below in reference to FIGS. 10-12. As such, intermediate layer 44 may include a different material than the materials of semiconductor layers 42 and 46. Depending on the design specifications of the ensuing hybrid transistor structure to electrically connect or isolate the source and drain regions subsequently formed within semiconductor layers 42 and 46, intermediate layer 44 may include dielectric, semiconductor, and/or conductive materials as specified in more detail below. An exemplary thickness range for intermediate layer 44 may be between approximately 10 nm and approximately 20 nm, however, larger or smaller thicknesses may be used. In particular, the thickness of intermediate layer 44 may vary depending on the specifications of the ensuing device and the fabrication technique used to fabricate intermediate layer 44.

In some embodiments, intermediate layer 44 may include a dielectric material, such as silicon dioxide, silicon nitride, silicon oxynitride, or any combination of such layers and, consequently, may electrically isolate the source and drain regions subsequently formed within semiconductor layers 42 and 46 when applicable. A dielectric material for intermediate layer 44 may be thermally grown from lower semiconductor layer 42 or may be deposited. Alternatively, intermediate layer 44 may include a semiconductor and/or a conductive material and, consequently, may electrically connect the source and drain regions subsequently formed within semiconductor layers 42 and 46 when applicable. For example, intermediate layer 44 may include a conductive material, such as but not limited to doped amorphous silicon, doped polysilicon, tantalum, titanium, tungsten, or any metal alloy, nitride or silicide thereof or any material to be made conductive by subsequent an introduction of dopants, such as undoped polysilicon, for example. Alternatively, intermediate layer 44 may include a semiconductor material, such as any of the ones noted above for semiconductor layers 42 and 46 as long as it differs from those selected for semiconductor layers 42 and 46. In such cases, the semiconductor material may be an epitaxial layer grown from lower semiconductor layer 42 or may be bonded to lower semiconductor layer 42.

In cases in which intermediate layer 44 includes a semiconductor material, upper semiconductor layer 46 may, in some embodiments, be grown as an epitaxial layer therefrom. Such a deposition technique may be particularly advantageous for forming upper semiconductor layer 46 with the same crystal orientation as intermediate layer 44 and, in cases in which intermediate layer 44 is an epitaxial layer grown from lower semiconductor layer 42, may be advantageous for forming upper semiconductor layer 46 with the same crystal orientation as lower semiconductor layer 42. It is generally recognized that epitaxial layers are robust materials with few impurities. In addition, epitaxial regrowth techniques are generally cost and time efficient. In other embodiments, however, upper semiconductor layer 46 may be bonded to intermediate layer 44. In general, bonding techniques take more time and are more costly than epitaxial regrowth, but they offer the advantage of being able to select the crystal orientation of upper semiconductor layer 46, particularly relative to lower semiconductor layer 42.

In some embodiments, it may be advantageous to form upper semiconductor layer 46 with a different crystalline orientation than lower semiconductor layer 42. For example, in embodiments in which the ensuing hybrid transistor structure is one of a pair of complementary MOS (CMOS) transistors and the other of the pair of CMOS transistors is a transistor having a single channel formed within lower semiconductor layer 42 (i.e., without having an overlying multiple-gate-sided channel transistor as in the hybrid transistor structure), it may be advantageous for semiconductor layers 42 and 46 to have different crystalline orientations. In particular, NMOS and PMOS transistors generally yield higher channel performances within respectively different crystalline orientations, namely (100) surface orientation and <100> channel direction for NMOS transistors and (110) surface orientation and <110> channel direction for PMOS transistors. As such, bonding upper semiconductor layer 46 to intermediate layer 44 in a manner in which to have a different crystalline orientation than lower semiconductor layer 42 may offer a topography in which CMOS transistors may be formed for optimum performance. In particular, one of the CMOS transistors may be formed within the ensuing hybrid transistor structure having a channel within a patterned portion of upper semiconductor layer 46 oriented in a first crystallographic direction and the other of the CMOS transistors may be electrically isolated from the hybrid transistor structure and have a channel within lower semiconductor layer 42 oriented in a second crystallographic direction. An exemplary layout of CMOS transistors fabricated from semiconductor topography 40 is illustrated in FIG. 22 and described in more detail below.

As noted above, lower semiconductor layer 42 may be patterned such that devices subsequently formed upon semiconductor topography 40 may be isolated. In particular, in embodiments in which substrate 43 includes a SOI substrate, semiconductor layer 42 may be patterned to expose an underlying insulating layer of the SOI substrate. In contrast, in embodiments in which substrate 43 is a bulk wafer substrate, semiconductor layer 42 may be patterned with field oxide regions. In either case, devices subsequently formed upon patterned regions of semiconductor layer 42 may be isolated from each other. The manner and time at which lower semiconductor layer 42 may be patterned within a fabrication sequence may vary. As such, although semiconductor layer 42 is described below in reference to FIGS. 4-7 as being patterned with intermediate layer 44 and upper semiconductor layer 46, the method described herein is not necessarily so limited. For example, in some embodiments, lower semiconductor layer 42 may be patterned prior to the formation of intermediate layer 44 and upper semiconductor layer 46. In other cases, lower semiconductor layer 42 may be patterned subsequent to the formation of intermediate layer 44 and upper semiconductor layer 46 and, in some embodiments, subsequent to the patterning of such layers.

In some cases, upper semiconductor layer 46, intermediate layer 44, and lower semiconductor layer 42 may be patterned in alignment with each other, such as described in reference to the different fabrication sequences depicted in FIGS. 4-7. In particular, FIGS. 4 and 5 illustrate upper semiconductor layer 46, intermediate layer 44, and lower semiconductor layer 42 patterned to have layout configuration 50. Illustrating an alternative pattern, FIGS. 6 and 7 depict upper semiconductor layer 46, intermediate layer 44, and lower semiconductor layer 42 patterned to have layout configuration 51. In general, FIGS. 4 and 6 illustrate partial plan views of semiconductor topography 40 subsequent to patterning the layout configurations and FIGS. 5 and 7 illustrate partial cross-sectional views of semiconductor topography 40 taken along line 56 of FIGS. 4 and 6, respectively.

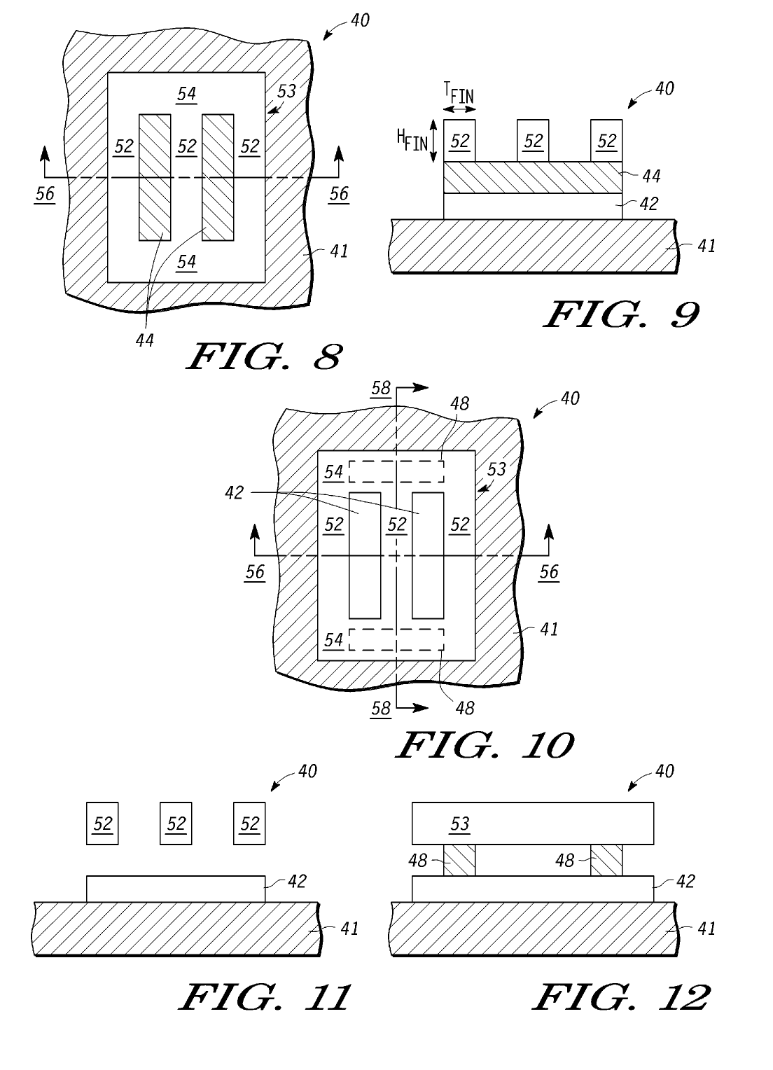

In some cases, the patterning process illustrated in FIGS. 4 and 5 may be advantageous for embodiments in which it is desirable for lower semiconductor layer 42 to have the same layout pattern as upper semiconductor layer 46, such as described for semiconductor layers 22 and 26 in reference to FIG. 1. A benefit of the etch alignment process illustrated in FIGS. 4 and 5 is that the fabrication process may continue directly to the selective etch of intermediate layer 44 described in reference to FIGS. 10-12 to suspend a portion of upper semiconductor layer 46 above lower semiconductor layer 42, saving process time and money. In other embodiments, however, it may be desirable for lower semiconductor layer 42 to have a different layout pattern than upper semiconductor layer 46, such as described for semiconductor layers 32 and 36 in reference to FIG. 2. In such cases, the method may follow the process depicted in FIGS. 6 and 7 and continue to FIGS. 8 and 9 to obtain the variation of patterns among semiconductor layers 42 and 46. In particular, remaining portions of semiconductor layer 46 depicted in FIGS. 6 and 7 may be patterned to form patterned semiconductor layer 53 having segments 52 extending between joining portions 54 as shown in the plan view of semiconductor topography 40 in FIG. 8.

A partial cross-sectional view of semiconductor topography 40 taken along line 56 of FIG. 8 is shown in FIG. 9. As shown in FIGS. 8 and 9, the subsequent patterning process of upper semiconductor layer 46 may expose regions of intermediate layer 44 and, in some embodiments, terminate within intermediate layer 44. In such cases, the etching process may be configured to remove the material of upper semiconductor layer 46 at a faster rate than the material of intermediate layer 44. In other cases, however, the patterning process may etch through exposed portions of intermediate layer 44 to expose lower semiconductor layer 42.

It is noted that the patterning of semiconductor layer 42, intermediate layer 44, and semiconductor layer 46 may follow other fabrication sequences and, therefore, are not restricted to the illustrations in FIGS. 4-9. For instance, semiconductor layer 46 may be patterned to have a layout configuration of patterned semiconductor layer 53 depicted in FIG. 8 prior to patterning semiconductor layer 42 in some embodiments. In such cases, semiconductor layer 42 may be patterned any time prior to forming a gate structure within the ensuing hybrid structure, including prior to or subsequent to the selective etch process of intermediate layer 44 described in more detail below in reference to FIGS. 10-12. In any case, the processes for patterning semiconductor layer 42, intermediate layer 44, and semiconductor layer 46 may generally include lithography techniques known in the semiconductor industry. In particular, a mask layer may be formed upon upper semiconductor layer 46 and exposed regions may be subsequently removed using any wet and/or dry etch techniques.

As noted above, the method described in reference to FIGS. 3-22 may be used to fabricate any hybrid transistor structure having a multiple-gate-sided channel transistor formed from a stacked configuration of spaced apart semiconductor layers as generally described in reference to FIGS. 1 and 2 and, therefore, the method is not necessarily restricted to the patterns of layers depicted in FIGS. 4-9. For example, in reference to FIG. 8, the shape, size, number, and spacing of segments 52 may vary. In addition, the shape and size of joining portions 54 between which segments 52 extend may vary. In some embodiments it may be advantageous for each of joining portions 54 to have larger areal dimensions than each of segments 52 such that portions of intermediate layer 44 may be retained as support structures during a subsequent etch process of the layer as described in more detail below. In any case, dimensional variations may also apply to the pattern layouts of 50 and 51 depicted in FIGS. 4-7 as well.

In general, semiconductor layer 46 may be patterned to have portions (e.g., segments 52 of patterned semiconductor layer 53 depicted in FIG. 9) with heights and thicknesses (denoted as H_{Fin} and T_{Fin} in FIG. 9) within design specifications for the multiple-gate-sided channel transistor subsequently formed within the ensuing hybrid transistor structure, particularly with regard to the effective gate length corresponding to the multiple-gate-sided transistor channel. In some cases, one or more of segments 52 may be configured to have heights of similar dimensions as their thicknesses. In other embodiments, however, it may be advantageous for T_{Fin}<<H_{Fin} as illustrated FIG. 9 to maintain relatively high layout efficiency. In addition, such a dimensional configuration of the fins induces the fabrication of a predominantly “vertical-sided” transistor channel. The term “vertical-sided transistor channel,” as used herein, may generally refer to a transistor channel having a larger height dimension than a width dimension. As described in more detail below, the transistor channels subsequently formed within segments 52 may be formed to be completely depleted. As such, in embodiments in which T_{Fin}<<H_{Fin}, the resulting transistor channel may have a larger height dimension than a width dimension. It is noted that the reference of a “vertical-sided” transistor does not refer to the direction of electron mobility within the channel. In the device described herein, the direction of electron mobility within the channel/s is generally parallel to the surface of substrate 43.

Regardless of the relativity of their thickness and height dimensions, all of segments 52 may, in some embodiments, include substantially similar dimensions. In other cases, however, one or more of segments 52 may include substantially different height and/or thickness dimensions than the other of segments 52. In any embodiment, an exemplary height range for segments 52 may be between approximately 5 nm and approximately 100 nm. Likewise, an exemplary thickness range for segments 52 may be between approximately 5 nm and approximately 100 nm. Larger or smaller thicknesses and/or heights, however, may be employed.

Subsequent to patterning semiconductor layer 42, intermediate layer 44, and semiconductor layer 46, remaining portions of intermediate layer 44 may be selectively etched to suspend a portion of semiconductor layer 46 above semiconductor layer 42. An exemplary depiction of such a selective etch process is depicted in FIGS. 10-12 following the formation of patterned semiconductor layer 53 in FIGS. 8 and 9. FIG. 10 illustrates a partial plan view of semiconductor topography 40 subsequent to intermediate layer 44 being etched and FIGS. 11 and 12 illustrate partial cross-sectional views of semiconductor topography 40 taken along lines 56 and 58 of FIG. 10, respectively. Support structures 48 are outlined by dotted lines in FIG. 10 to indicate their position between joining portions 54 of patterned semiconductor layer 53 and respective underlying surfaces of lower semiconductor layer 42. Although the process steps described in reference FIGS. 10-12 as well as subsequent process steps described in reference to FIGS. 13-22 are specific to embodiments of semiconductor topography 40 having the configuration depicted in FIGS. 8 and 9, the method described herein in not necessarily so limited. In particular, the fabrication steps described in reference to FIGS. 10-22 may alternatively be followed for embodiments of semiconductor topography 40 having the configuration depicted in FIGS. 4 and 5 or any other configuration of the layers which allow the fabrication of a hybrid transistor structure.

As shown in FIGS. 10-12, exposed portions of intermediate layer 44 may be removed, in turn exposing portions of lower semiconductor layer 42. In addition, portions of intermediate layer 44 underlying segments 52 and joining portions 54 may be undercut such that at least portions of segments 52 are suspended above lower semiconductor layer 42. More specifically, the etch process may be controlled such that portions of intermediate layer 44 remain as support structures 48 under joining portions 54 of patterned semiconductor layer 53. As noted above, it may be advantageous for each of joining portions 54 to have larger areal dimensions than each of segments 52 such that portions of intermediate layer 44 may be retained as support structures during the etch process. In some embodiments, the etch process may be particularly selective for removing the material of intermediate layer 44 at a faster rate than the materials of patterned semiconductor layer 53 and lower semiconductor layer 42 such that portions of patterned semiconductor layer 53 and lower semiconductor layer 42 are not deteriorated by the etching process. For example, an etch chemistry which may etch silicon germanium (e.g., comprising intermediate layer 44) at a faster rate than silicon (e.g., comprising patterned semiconductor layer 53 and lower semiconductor layer 42) may include hydrofluoric acid and/or ammonium hydroxide. Other etch chemistries, however, may be used for such a combination of materials. In addition, several other combination of materials may be used for lower semiconductor layer 42, intermediate layer 44, and patterned semiconductor layer 53, and, consequently, other etch chemistries suitable for facilitating etch selectivity between different materials may be used.

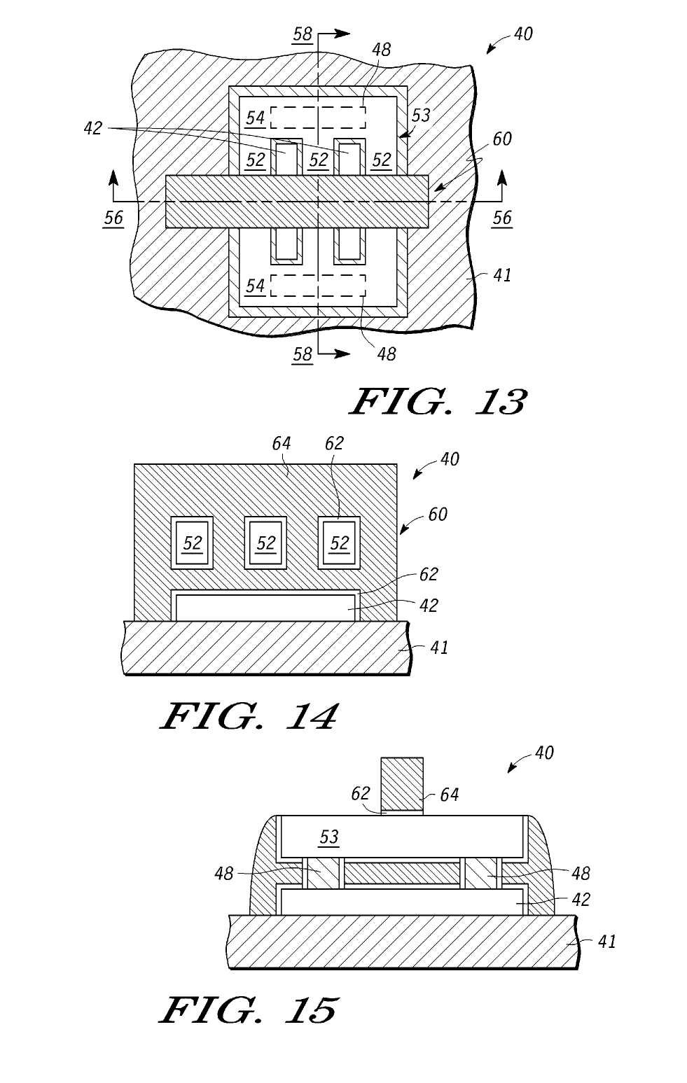

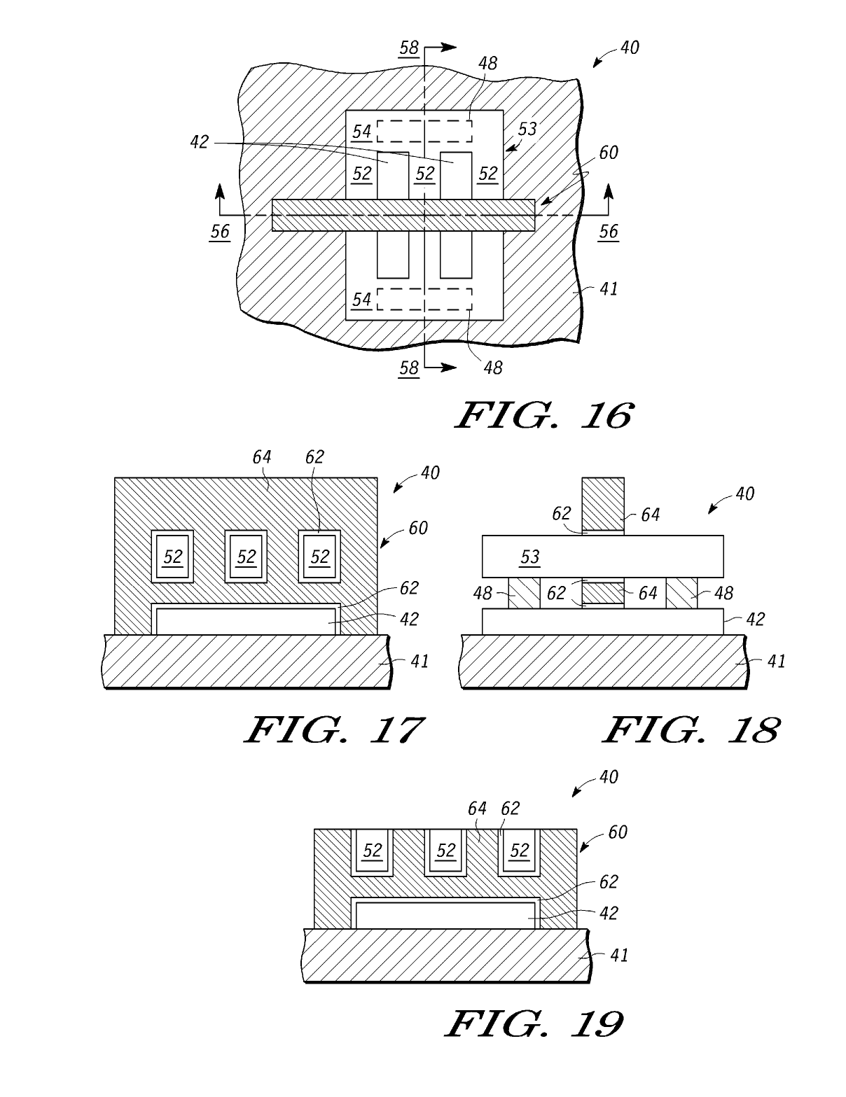

FIGS. 13-18 illustrate the formation of gate 66 in a region of semiconductor topography 40 comprising suspended portions of segments 52. In particular, FIGS. 13 and 16 illustrate partial plan views of semiconductor topography 40 during a sequence of etch steps in which transitional structure 60 and gate structure 66 are successively formed. In addition, FIGS. 14 and 15 as well as FIGS. 17 and 18 illustrate partial cross-sectional views of semiconductor topography 40 taken along lines 56 and 58 of FIGS. 13 and 16, respectively.

In general, the formation of gate 66 may include forming gate dielectric layers 62 upon exposed surfaces of patterned semiconductor layer 53 and lower semiconductor layer 42. In other words, gate dielectric layers 62 are formed upon the surfaces of patterned semiconductor layer 53 and lower layer 42 not in contact with support structures 48 and, thus, are formed surrounding suspended portions of segments 52 and upon exposed surfaces of lower semiconductor layer 42 as well as upon other exposed portions of patterned semiconductor layer 53. In addition, gate dielectric layers 62 may be formed upon exposed peripheries of support structures 48 in embodiments in which intermediate layer 44 includes a silicon-based semiconductor material. In embodiments in which intermediate layer 44 is a metallic material, metal oxide may be formed upon the sidewalls of support structures 48 during the formation of gate dielectric layers 62. In contrast, in embodiments in which intermediate layer 44 is a dielectric layer, no additional material may be formed along the sidewalls of support structures 48 during the formation of gate dielectric layers 62.

In some embodiments, the formation of the gate dielectric layers 62 may include a thermal oxidation process in which semiconductor topography 40 is exposed to an ambient of oxygen at a temperature greater than approximately 1000° C. such that exposed surfaces of patterned semiconductor layer 53, lower semiconductor layer 42 and, in some cases, support structures 48 are transposed into dielectric materials. In other cases, gate dielectric layers 62 may be deposited, such as by chemical vapor deposition or atomic layer deposition techniques. In any case, the thickness of gate dielectric layers 62 may generally be between approximately 10 angstroms and approximately 100 angstroms, but larger or smaller thicknesses may be employed.

Subsequent to forming gate dielectric layers 62, gate electrode layer 64 may be deposited upon semiconductor topography 40. In some cases, gate electrode layer 64 may include a conductive material, such as but not limited to doped polysilicon, tantalum, titanium, tungsten, or any metal alloy thereof. In alternative embodiments, gate electrode layer 64 may include a material to be made conductive by a subsequent introduction of dopants, such as undoped polysilicon, for example. In any case, gate electrode layer 64 may be deposited in a manner such that the material is interposed between patterned semiconductor layer 53 and lower semiconductor layer 42 as well as alongside and, in some cases, above patterned semiconductor layer 53. Exemplary deposition techniques which are capable of depositing materials in such a manner include but are not necessarily limited to atomic layer chemical vapor deposition (ALCVD) and low pressure chemical vapor deposition (LPCVD).

As shown in FIGS. 13-15, gate electrode layer 64 and, in some cases, gate dielectric layers 62 may be patterned in a region of semiconductor topography 40 comprising suspended portions of segments 52 to form transitional structure 60. In particular, gate electrode layer 64 and, in some cases, gate dielectric layers 62 may be patterned to extend across one or more of segments 52 and across portions of lower substrate portion 41 on either side of lower semiconductor layer 42 as shown in FIGS. 13 and 14. As shown in FIG. 15, the etch process used to form transitional structure 60 may be configured to form electrode material spacers along the sidewalls of patterned semiconductor layer 53 and lower semiconductor layer 42, including around the periphery of such layers as well as along the openings of patterned semiconductor layer 53 between segments 52. As further shown in FIG. 13, the etch process may, in some embodiments, be conducted to expose portions of lower semiconductor layer 42 between segments 52. In other cases, the etch process may terminate before exposing portions of lower semiconductor layer 42 between segments 52. In either embodiment, an etch technique that may be used to form electrode material spacers as well as be etch-selective to semiconductor layer 42 may be reactive ion etching or any other etch technique with such capabilities.

As shown in FIG. 13, transitional structure 60 is patterned to have a width substantially larger than segments 52. Such a variance in width allows a subsequent etch process to remove electrode material underlying segments 52 while narrowing transitional structure 60 to a desired width for gate 66. In particular, an isotropic etch process may be used subsequent to the formation of transitional structure 60 to remove the electrode material spacers as well as portions of gate electrode layer 64 between patterned semiconductor layer 53 and underlying portions of semiconductor layer 42. In addition, the isotropic etch process simultaneously narrows the width of transitional structure 60 to form gate 66 shown in FIGS. 16-18.

As shown in FIGS. 16-18, resulting gate 66 is disposed along multiple sides of suspended portions of segments 52 as well as coupled to and interposed between the suspended portions of segments 52 and underlying portions of lower semiconductor layer 42. In this manner, gate 66 may, in some cases, subsequently serve as a plurality of multiple-sided gate structures (i.e., about suspended portions of segments 52) for the ensuing hybrid transistor device. Alternatively stated, gate 66 may be patterned as a structure which is common to a plurality of multiple-gate-sided transistor channels subsequently formed within the ensuing hybrid transistor device. As noted above, the method described in reference to FIGS. 3-22 may be employed to form a hybrid transistor structure having any number of multiple-gate-sided channels and, therefore, gate 66 may alternatively be formed as a structure which is common to one multiple-gate-sided transistor channel of an ensuing hybrid transistor device.

Regardless of the number of segments suspended within patterned semiconductor layer 53, lower semiconductor layer 42 may, in some embodiments, include a transistor channel as described in more detail below in reference to FIG. 21. In some cases, the transistor channel within lower semiconductor layer 42 may be a multiple-gate-sided transistor channel due to an elevation difference between semiconductor layer 42 and lower substrate portion 41. More specifically, gate 66 may be arranged upon the upper surface and the sidewalls of lower semiconductor layer 42 as shown in FIG. 17, particularly in cases in which substrate 43 is a SOI substrate. Consequently, gate 66 may be common to a multiple-gate-sided transistor channel within semiconductor layer 42 as well as one or more multiple-gate-sided transistor channels within patterned semiconductor layer 53. In other cases, gate 66 may be common to a single-gate-sided transistor channel within semiconductor layer 42 and one or more multiple-gate-sided transistor channels within patterned semiconductor layer 53. In particular, the patterned portion of semiconductor layer 42 may be surrounded by field oxide regions which are substantially coplanar with the semiconductor layer, particularly in embodiments in which substrate 43 includes a bulk wafer substrate, and, thus, the transistor channel within semiconductor layer 42 may be a single-gate-sided transistor channel. In yet other embodiments, a channel region may not be subsequently formed within lower semiconductor layer 42 and, therefore, gate 66 may only correspond to multiple-gate-sided transistor channels formed within patterned semiconductor layer 53.

In any case, as shown in FIGS. 16-18, gate 66 may be formed to surround all sides of segments 52, effectively forming all-sided-gate structures. As a consequence, the surrounded portions of segments 52 may be formed as all-around-gate transistor channels. In alternative embodiments, however, gate 66 may be formed around less than all sides of segments 52. For example, gate 66 may alternatively be formed such that gate electrode layer 64 and, in some cases, gate dielectric layers 62 are not arranged above segments 52, such as shown in FIG. 19. In particular, FIG. 19 illustrates an exemplary alternative configuration of semiconductor topography 40 in which gate 66 is formed interposed between portions of segments 52 and lower semiconductor layer 42 and along sidewall portions of segments 52, but not above segments 52. As a result, gate 66 includes three-sided-gate structures rather than all-around-gate structures about segments 52. An exemplary manner in which to fabricate such a structure may include polishing or etching back gate electrode layer 64 and dielectric layer 62 until segments 52 are exposed. In other cases, portions of dielectric layer 62 may be retained above segments 52. In either case, the polishing or etching back process may be performed prior to or subsequent to patterning gate electrode layer 64 to form gate 66.

Subsequent to forming gate 66, source and drain regions may be formed within semiconductor topography 40, particularly within portions of patterned semiconductor layer 53 not embedded or contained by gate 66 and, in some cases, portions of lower semiconductor layer 42 not covered by gate 66. As used herein, the terms “embedded” and “contained” may refer a structure which is bound by a material on opposing sides of the structure. The reference, however, does not necessarily infer encapsulation by the material and, therefore, may apply to portions of segments 52 being coplanar with gate 66 shown in FIG. 19. As noted below, the formation of the source and drain regions may, in some embodiments, include the implantation of dopants. It is noted, however, that other doping methods may be used, such as but not limited to solid source diffusion techniques (e.g., plasma assisted doping).

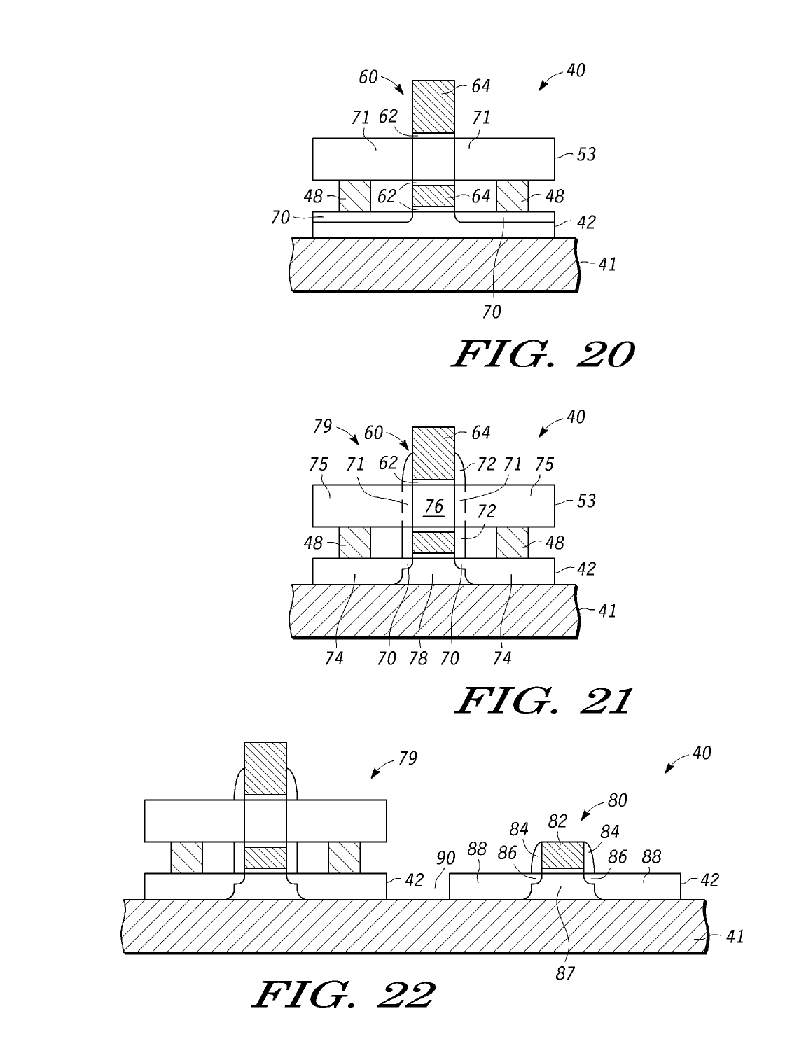

In some embodiments, the formation of the source and drain regions may include the formation of lightly doped regions within patterned semiconductor layer 53 and, in some cases, within lower semiconductor layer 42 as shown in FIG. 20. In particular, FIG. 20 illustrates the formation of lightly doped regions 70 and 71 subsequent to the formation of gate 66 described in reference to FIGS. 16-18. In cases in which lightly doped regions 70 are formed within lower semiconductor layer 42, the introduction of dopants to form lightly doped regions 70 and 71 may be sufficient to diffuse through portions of patterned semiconductor layer 53 not embedded by gate structure 66 and portions of support structures 48 to introduce dopants into underlying surface portions of lower semiconductor layer 42. As such, the formation of lightly doped regions 70 and 71 may, in some embodiments, be governed by the design specifications of lightly doped regions 70. For example, in some cases, the dopant introduction process may be configured to form lightly doped regions 70 at a relatively shallow depth, such as between approximately 100 angstroms and approximately 1000 angstroms, after anneal processes, such as the one described below. Exemplary process conditions used to implant dopants to form lightly doped regions 70 and 71 may include ion doses between approximately 5×10¹³ cm⁻² and approximately 1×10¹⁵ cm⁻² as well as energies between approximately 0.5 kilo-electrovolts (KeV) and approximately 30 KeV, depending on the dopant implanted and the depth of the layers within semiconductor topography 40. Larger or smaller ion doses and/or energies, however, may be used.

In yet other embodiments, lightly doped regions 70 and 71 may not be formed within lower semiconductor layer 42 and upper patterned semiconductor layer 53. In particular, although lightly doped regions may increase the hot-carrier reliability of transistors fabricated from the ensuing hybrid transistor structure, lightly doped regions may be omitted from semiconductor topography 40 in some cases. In yet other embodiments, the formation of lightly doped regions may be limited to patterned semiconductor layer 53 on either side of gate 66. In such cases, the fabrication process may be configured to prohibit an ensuing transistor from being formed within lower semiconductor layer 42. In particular, the ensuing hybrid transistor structure may be fabricated to have multiple-gate-sided channels within segments 52 but not a transistor channel within underlying portions of lower semiconductor layer 42. In any case, other diffusion regions, such as halo regions and/or channel stop regions may, in some embodiments, be formed within exposed portions of patterned semiconductor layer 53 and, in some cases, may be further formed within lower semiconductor layer 42. Such diffusion regions are not shown in FIG. 20 to simplify the drawing and, therefore, should not be presumed to be necessarily omitted. In any case, the thickness and material of the portion of gate 66 overlying segments 52 may sufficient to block the implantation of dopants within underlying portions of segments 52. In other cases, a capping layer may be formed upon gate 66 to prevent an implantation of dopants within such portions of segments 52.

As shown in FIG. 21, spacers 72 may be formed along the sidewalls of gate 66 subsequent to the formation of lightly doped drain regions 70 and 71. In addition, source and drain regions 74 and 75 may be respectively formed in alignment with spacers 72 within lower semiconductor layer 42 and patterned semiconductor layer 53. In yet other embodiments, the formation of lightly doped drain regions may be omitted from the fabrication sequence of the ensuing hybrid transistor structure. In such cases, spacers 72 may be formed subsequent to the formation of source and drain regions 75. Consequently, source and drain regions 75 may be formed in alignment with gate 66 within exposed portions of patterned semiconductor layer 53 and, in some cases, source and drain regions 74 may be formed within lower semiconductor layer 42. Subsequent thereto, spacers 72 may be formed along the sidewalls of gate 66 for the fabrication of silicides.

The formation of spacers 72 may generally be formed by depositing an insulating material, such as but not limited to silicon dioxide, silicon nitride, or silicon oxynitride, such that the material is interposed between patterned semiconductor layer 53 and lower semiconductor layer 42 as well as alongside and, in some cases, above patterned semiconductor layer 53. An etch process may follow which includes aniostropically etching the insulating layer such that sidewall spacers are formed along gate 66 and semiconductor layers 53 and 42. In some cases, retaining spacers along semiconductor layers 53 and 42 during subsequent processing may be acceptable. In other embodiments, however, it may be advantageous to remove spacers formed along semiconductor layers 53 and 42. For instance, in some cases, it may be advantageous to expose the side of semiconductor layer 53 and/or 42 such that contact may be made to the surfaces. As such, in some cases, the anisotropic etch may be extended to remove the spacers formed along semiconductor layers 53 and 42. As shown in FIGS. 16-21, the portion of gate 66 overlying segments 52 comprises a significantly larger thickness than the thicknesses of semiconductor layers 53 and 42. Consequently, an extension of the anisotropic etch may remove spacers along semiconductor layer 53 and 42 prior to removing the entirety of the spacers along the portion of gate 66 over lying segments 52.

In addition to removing spacers along the portion of semiconductor layers 53 and 42, it may be advantageous, in some embodiments, to remove the insulating material remaining between patterned semiconductor layer 53 and lower semiconductor layer 42 prior to any further processing. Since an anisotropic etching process may not be suitable for removing material in such a region while retaining spacers along gate 66, the spacer formation process may include an additional etching process. In particular, the spacer formation process may include subsequently etching the insulating material in an isotropic manner such that portions of the insulating material are retained along the sidewalls of gate 66 (both over and under segments 52) but are removed within regions extending to support structures 48. As a result of such an isotropic etch, the height of the spacers formed along the portion of gate 66 over segments 52 may be reduced relative to the height of the portion of gate 66 as depicted in FIG. 21. In alternative embodiment, gate 66 and spacers formed there along may be masked subsequent to the anisotropic etch used to form the spacers. In such an embodiment, remaining portions of the insulating material between semiconductor layer 53 and lower semiconductor layer 42 may be removed without reducing the height of spacers along gate 66. In some cases, such a mask and etch process sequence may be additionally or alternatively used to remove spacers along semiconductor layers 53 and 42 such that an extension of the anisotropic etch may be omitted. In some cases, however, it may be desirable to avoid masking operations since they tend to be problematic due to alignment issues.

As noted above, FIG. 21 illustrate the formation of source and drain regions 74 and 75 in addition to spacers 72. In particular, FIG. 21 illustrates the distinction of source and drain regions 75 from lightly doped regions 71 within patterned semiconductor layer 53 by a dotted line. In contrast, the distinction of source and drain regions 74 and lightly doped regions 70 within lower semiconductor layer 42 is illustrated by the depths in which the regions extend within the layer. In some cases, dopants may be implanted at a sufficient energy such that source and drain regions 74 are formed to a desired depth within lower semiconductor layer 42, such as between approximately 900 angstroms and approximately 1500 angstroms after a subsequent anneal process, for example. An exemplary range of implant energies may be between approximately 1 KeV and approximately 50 KeV and an exemplary range of doses may be between approximately 1×10¹⁵ cm⁻² and approximately 8×10¹⁵ cm⁻², depending on the dopant implanted and the depth of the layers within semiconductor topography 40. Larger or smaller ion doses and/or energies, however, may be used to form source and drain regions 74 and 75 in some embodiments. In alternative embodiments, the fabrication process may be limited to the formation of source and drain regions 75 within exposed portions of patterned semiconductor layer 53 following the formation of spacers 72, such as in embodiments in which the formation of lightly doped drain regions are restricted to patterned semiconductor layer 53. In such cases, the fabrication process may be configured to prohibit an ensuing transistor from being formed within lower semiconductor layer 42 as described above.

In any case, semiconductor topography 40 may be annealed to activate the implanted impurities and eliminate defects created by the implantation of dopants to form source and drain regions 75 and, in some cases, source and drain regions 74. In some embodiments, a rapid thermal anneal (RTA) process may be employed. In particular, semiconductor topography 40 may be exposed to a relatively high temperature, such as between approximately 600° C. and approximately 1100° C., for less than a minute and, more preferably for approximately 20 seconds or less. Higher or lower temperatures and/or longer or short durations, however, may be employed for the anneal process, depending on the design specifications of the topography.

Due to the implantation of source and drain regions 75 within exposed regions of patterned semiconductor layer 53, multiple-gate-sided transistor channels 76 are formed within the portions of segments 52 surrounded by multiple-sided gate structure 66. As a consequence, resulting hybrid transistor structure 79 includes a transistor having a plurality of multiple-gate-sided transistor channels 76 to which multiple-sided gate structure 66 is common. In addition, the transistor includes source and drain regions 75 extending from multiple-gate-sided transistor channels 76 along segments 52 to and including joining portions 54. In cases in which source and drain regions 74 are formed within exposed regions of lower semiconductor layer 42, transistor channel 78 is formed therebetween. In such embodiments, resulting hybrid transistor structure 79 may include another transistor having a transistor channel to which multiple-sided gate structure 66 is further common. In particular, resulting hybrid transistor structure 79 may include one transistor including a transistor channel within lower semiconductor layer 42 and another transistor having a plurality of multiple-gate-sided transistor channels within patterned semiconductor layer 53, both of which share a common gate. In other embodiments, the source and drain regions 75 and 74 respectively formed within patterned semiconductor layer 53 and lower semiconductor layer 42 may be electrically connected by support structures 48 and, thus, hybrid transistor structure 79 may include a single transistor having a plurality of multiple-gate-sided transistor channels within patterned semiconductor layer 53 stacked above transistor channel within lower semiconductor layer 42.

In any case, channel 76 depicted in FIG. 21 may be one of a plurality of multiple-gate-sided transistor channels common to the source and drain regions within the other portions of patterned semiconductor layer 53. In other embodiments, however, channel 76 depicted in FIG. 21 may be the only channel of a transistor fabricated within patterned semiconductor layer 53. In particular, as noted above, patterned semiconductor layer 53 may alternatively be formed to have a single suspended segment 52 and, consequently, the method described herein may alternatively to be used to form a hybrid transistor structure having a transistor with a single multiple-gate-sided transistor channel. In any case, multiple-gate-sided transistor channel 76 may, in some embodiments, be a vertical-sided transistor channel in some cases. As noted above, the term “vertical-sided transistor channel,” as used herein, may generally refer to a transistor channel having a larger height dimension than a width dimension. In embodiments in which T_{Fin}<<H_{Fin} within segments 52, the resulting transistor channel may have a larger height dimension than a width dimension. It is noted that the reference of a “vertical-sided” transistor does not refer to the direction of electron mobility within the channel. In the device described herein, the direction of electron mobility within the channel/s is generally parallel to the surface of substrate 43.

In some embodiments, the hybrid transistor structure illustrated in FIG. 21 may be one of a plurality of hybrid transistor structures formed within semiconductor topography 40. The plurality of hybrid transistor structures is not shown in the figures to simplify the drawings. In such cases, upper semiconductor layer 46 and lower semiconductor layer 42 may be patterned to have at least two distinct portions or segments. In addition, separate gate structures may be formed in the vicinity of each pair of the distinct segments. In this manner, the two hybrid transistor structures may be electrically isolated. In general, the two hybrid transistor structures may include any of the device configurations described above in reference to FIGS. 1-21. In particular, each of the distinct segments of upper semiconductor layer 46 may include a multiple-gate-sided transistor channel and source and drain regions extending therefrom. In addition, one or both of the distinct segments of lower semiconductor layer 42 may include a transistor channel and source and drain regions extending therefrom or, alternatively, one or both of the distinct segments of lower semiconductor layer 42 may be void of any such regions. Furthermore, the distinct segments of upper semiconductor layer 46 and lower semiconductor layer 42 as well as the gates within the two hybrid transistor structures may include the same or different pattern layouts.

In some embodiments, two hybrid transistor structures may be formed as a pair of CMOS transistors, specifically one of the hybrid transistor structures formed having an NMOS transistor and other of the hybrid transistor structures formed having a PMOS transistor. In such cases, the NMOS and PMOS transistors may include any of the configurations described in reference to FIGS. 1-21. In some embodiments, the CMOS transistors may include the same configuration. For example, in some cases, the CMOS transistors may include the same number of channels within an upper semiconductor layer and, in some embodiments, further include a channel within a lower semiconductor layer. In addition, the CMOS transistors may have support structures configured as insulators or conductors. Furthermore, the dimensions of the respective gate structures may be similar. In other cases, the CMOS transistors may comprise different configurations, including respective variations of any one or more of the features described in reference to FIGS. 1-21.

In yet other embodiments, a hybrid transistor structure may be formed as one of a pair of CMOS transistors and the other of the pair of CMOS transistors may be formed from a different type of transistor structure, such as one which does not include a stacked configuration of semiconductor layers. An exemplary depiction of a pair of CMOS transistors having such dueling structural configurations is illustrated in FIG. 22. In particular, FIG. 22 illustrates transistor 80 formed within semiconductor topography 40 along with hybrid transistor structure 79. As shown in FIG. 22, transistor 80 includes gate 82 disposed over a portion of lower semiconductor layer 42 electrically isolated from hybrid transistor structure 79. In some cases, the electrical isolation may be gap 90 within an upper portion of lower semiconductor layer 42 corresponding to a layer arranged upon an insulating layer of an SOI substrate, as shown in FIG. 22. In such cases, gap 90 may expose the insulating layer of the SOI substrate such that remaining regions of lower semiconductor layer 42 are distinct. In other embodiments, electrical isolation may be a field oxide isolation region formed within lower semiconductor layer 42. In either case, since the portions of lower semiconductor layer 42 including transistor 80 and hybrid transistor structure 79 are respectively isolated from each other, the source and drain regions of transistor 80 are electrically isolated from the source and drain regions formed within hybrid transistor structure 79.

As shown in FIG. 22, the region of semiconductor topography 40 comprising transistor 80 does not include a region of patterned semiconductor layer 53 thereover. Consequently, transistor 80 includes a single channel formed within lower semiconductor layer 42. In some cases, transistor 80 may include lightly doped regions 86 and spacers 84, which source and drain regions 88 extending from channel 87 are aligned. In other embodiments, however, lightly doped regions 86 may be omitted from transistor 80. In some cases, lightly doped region 86 and/or source and drain regions 88 may be formed in conjunction with the corresponding regions of hybrid transistor structure 79. In other cases, the lightly doped regions and source and drain regions may be formed separately, such as for the formation of CMOS transistors as noted below. In either case, spacers 84 may, in some embodiments, be formed in conjunction with spacers 72. In addition, gate 82 may, in some embodiments, be formed in conjunction with gate 66 of hybrid transistor structure 79. In particular, the process of patterning gate electrode layer 64 and, in some cases, dielectric layer 62 to form gate 66 may further include patterning gate electrode layer 64 in a different region of semiconductor topography 40 not including patterned semiconductor layer 53 to form gate 82. In yet other embodiments, gates 60 and 82 and/or spacers 72 and 84 may be formed separately from each other.

As noted above, hybrid transistor structure 79 and transistor 80 may, in some embodiments, be formed as a pair of CMOS transistors, specifically hybrid transistor structure 79 formed having an NMOS transistor and transistor 80 formed as a PMOS transistor or vice versa. In such cases, hybrid transistor structure 79 may include any of the device configurations described above in reference to FIGS. 1-21. As noted above, upper semiconductor layer 46 from which patterned semiconductor layer 53 is formed may be arranged to have a different crystalline orientation than lower semiconductor layer 42. Such an arrangement may be particularly advantageous in embodiments in which a hybrid transistor structure 79 is formed as one of a pair of CMOS transistors with the other of the CMOS transistors not having a channel formed within an elevated semiconductor layer, such as patterned semiconductor layer 53. In particular, NMOS and PMOS transistors may be formed with opposing crystalline orientations, optimizing their respective performances. The configuration of hybrid transistor structure 79 and transistor 80 as CMOS transistors, however, is not necessarily restricted to semiconductor layer 42 and 46 having different crystalline orientations.

In general, the formation of the source and drain regions in the respective transistor structures may be formed separately for the configuration of CMOS transistors. In particular, the formation of source and drain regions within the structures may include masking the region of semiconductor topography 40 comprising gate 82 as well as adjacent portions of lower semiconductor layer 42 extending to gap 90. Subsequent thereto, a first set of dopants of a first conductivity type may be introduced within semiconductor topography 40 to form source and drain regions within hybrid transistor structure 79 and, more specifically, within the region of semiconductor topography 40 comprising patterned semiconductor layer 53. In addition, the region of semiconductor topography 40 comprising gate 66 as well as adjacent portions of patterned semiconductor layer 53 and lower semiconductor layer 42 extending to gap 90 may be masked. Subsequent thereto, a second set of dopants of opposite conductivity type to the first set of dopants may be introduced within semiconductor topography 40 to form source and drain regions within transistor 80 and, more specifically, within the region of semiconductor topography 40 not comprising patterned semiconductor layer 53. It is noted that the order in which the source and drain regions are formed within hybrid transistor structure 79 and transistor 80 is not specific to the method recited herein and, therefore, may be reversed in some cases.

It will be appreciated to those skilled in the art having the benefit of this disclosure that this invention is believed to provide a transistor formed from a stacked configuration of spaced apart semiconductor layers and methods for fabricating such a structure. Further modifications and alternative embodiments of various aspects of the invention will be apparent to those skilled in the art in view of this description. For example, the methods described herein are not limited to the structural configurations of components illustrated in the figures, particularly in regard to forming any number of distinct suspended portions within an upper semiconductor layer. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A semiconductor topography, comprising:
a first semiconductor layer having a first transistor channel and source and drain regions extending from the first transistor channel;
a second semiconductor layer spaced below the first semiconductor layer;
a gate structure having a portion coupled to and interposed between the region of the first semiconductor layer having the first transistor channel and an underlying surface of the second semiconductor layer; and
support structures coupled to and interposed between the regions of the first semiconductor layer including the source and drain regions and respective underlying surfaces of the second semiconductor layer, wherein the support structures include a material having different etch characteristics than materials of the first and second semiconductor layers.

2. The semiconductor topography of claim 1, wherein the second semiconductor layer comprises:
a second transistor channel underlying the gate structure; and
source and drain regions extending from the second transistor channel such that at least one of the support structures is interposed between respective source regions of the first and second semiconductor layers and at least another of the support structures is interposed between portions of the respective drain regions of the first and second semiconductor layers.

3. The semiconductor topography of claim 2, wherein the at least one and another support structures comprise a material configured to electrically connect the portions of the respective source regions and the portions of the respective drain regions.

4. The semiconductor topography of claim 2, wherein the at least one and another support structures comprise a dielectric material configured to electrically isolate the portions of the respective source regions and the portions of the respective drain regions.

5. The semiconductor topography of claim 1,
wherein the second semiconductor layer includes a region isolated from the surfaces underlying the gate structure, the support structures, and the first semiconductor layer;
wherein the isolated region comprises a separate transistor channel and source and drain regions extending from the separate channel; and
wherein the semiconductor topography comprises a separate gate structure arranged upon the separate transistor channel.

6. The semiconductor topography of claim 1, wherein the first semiconductor layer comprises a segment isolated from the first transistor channel and source and drain regions extending from the first transistor channel, wherein the segment comprises a second transistor channel and source and drain regions extending from the second transistor channel, and wherein the semiconductor topography further comprises:
a different gate structure extending from the portion of the segment including the second transistor channel to a different underlying surface of the second semiconductor layer; and
different support structures extending from the portions of the segment including the source and drain regions extending from the first transistor channel to respective different underlying surfaces of the second semiconductor layer.

7. The semiconductor topography of claim 1, wherein the first and second semiconductor layers include substantially equivalent pattern layouts.

8. The semiconductor topography of claim 1, wherein the first and second semiconductor layers include substantially different pattern layouts.

9. The semiconductor topography of claim 1, wherein the first transistor channel is a vertical-sided transistor channel.

10. The semiconductor topography of claim 1, wherein the first transistor channel comprises portions aligned along at least opposing sidewalls of the first semiconductor layer.

11. The semiconductor topography of claim 1, wherein the first semiconductor layer comprises a different crystalline orientation than the second semiconductor layer.

12. The semiconductor topography of claim 1, wherein the first and second semiconductor layers comprise monocrystalline silicon and the support structures comprise silicon-germanium.

13. A semiconductor topography comprising a first field effect transistor which comprises:
a first transistor channel arranged within a lower semiconductor layer of the semiconductor topography;
a second transistor channel arranged within an upper semiconductor layer spaced above the lower semiconductor layer;
a gate structure common to the first and second transistor channels; and
source and drain regions arranged within the upper and lower semiconductor layers and respectively extending from the first and second transistor channels, wherein portions of the source and drain regions within the upper semiconductor layer are electrically connected to portions of the source and drain regions within the lower semiconductor layer by an intermediate layer spaced adjacent to a portion of the gate structure interposed between the upper and lower semiconductor layers.

14. The semiconductor topography of claim 13, wherein the first field effect transistor is one of a pair of CMOS transistors, and wherein the other of the pair of CMOS transistors is a transistor having a single transistor channel, and wherein the single transistor channel is arranged within a region of the lower semiconductor layer isolated from the first field effect transistor.

15. The semiconductor topography of claim 13, wherein the first field effect transistor is one of a pair of CMOS transistors, and wherein the other of the pair of CMOS transistors comprises:
a third transistor channel arranged within a segment of the upper semiconductor layer isolated from the first field effect transistor;
a fourth transistor channel arranged within a segment of the lower semiconductor layer isolated from the first field effect transistor.

16. A method for processing a semiconductor topography, comprising:
patterning an upper semiconductor layer which is arranged above an intermediate layer within the semiconductor topography;
selectively etching the intermediate layer to suspend a portion of the patterned upper semiconductor layer above a lower semiconductor layer underlying the intermediate layer;
forming gate dielectric layers upon exposed surfaces of the upper and lower semiconductor layers subsequent to selectively etching the intermediate layer;
depositing a gate electrode layer upon the semiconductor topography subsequent to forming the gate dielectric layers;
patterning the gate electrode layer in a region of the semiconductor topography comprising a suspended portion of the patterned upper semiconductor layer; and
introducing dopants within the semiconductor topography to form source and drain regions within portions of the upper patterned semiconductor layer not embedded by the patterned gate electrode layer.

17. The method of claim 16, wherein the step of introducing the dopants further comprises introducing dopants within the semiconductor topography to form source and drain regions within portions of the lower semiconductor layer not covered by the patterned gate electrode layer.

18. The method of claim 16, wherein the step of patterning the upper semiconductor layer further includes patterning the intermediate layer and the lower semiconductor layer in alignment with the upper semiconductor layer.

19. The method of claim 18, further comprising repatterning portions of the upper semiconductor layer subsequent to patterning the intermediate layer and the lower semiconductor layer such that the upper and lower semiconductor layers have substantially different pattern layouts.

20. The method of claim 16, further comprising growing an epitaxial semiconductor material upon the intermediate layer to form the upper semiconductor layer.

21. The method of claim 16, further comprising bonding a semiconductor wafer to the intermediate layer to form the upper semiconductor layer.

22. The method of claim 16, wherein the intermediate layer is a dielectric material.

23. The method of claim 16, wherein the intermediate layer includes a material having different etch characteristics than materials of the upper and lower semiconductor layers.

24. The method of claim 16, wherein the lower layer is formed above a silicon-on-insulator substrate.
